(19) United States
(12) Patent Application Publication
(10) Pub. No.: US 2018/0123064 A1
(43) Pub. Date: May 3, 2018

(54) METHOD OF MANUFACTURING THIN FILM TRANSISTOR, THIN FILM TRANSISTOR, AND ELECTRONIC DEVICE COMPRISING THE THIN FILM TRANSISTOR

(71) Applicant: Samsung Electronics Co., Ltd., Suwon-si (KR)

(72) Inventors: Ajeong Choi, Suwon-si (KR); Joo Young Kim, Hwanseong-si (KR); Youngjun Yun, Yongin-si (KR); Yong-Uk Lee, Gwangju-si (KR); Jiyoung Jung, Seoul (KR)

(73) Assignee: Samsung Electronics Co., Ltd., Suwon-si (KR)

(21) Appl. No.: 15/784,733

(22) Filed: Oct. 16, 2017

(30) Foreign Application Priority Data
Oct. 27, 2016 (KR) 10-2016-0141282

(51) Int. Cl. H01L 51/05; H01L 51/00

(52) U.S. Cl. CPC H01L 51/0533; H01L 51/0002

(57) ABSTRACT

A method of manufacturing an organic thin film transistor includes forming a gate insulating layer on a gate electrode, forming a mold on the gate insulating layer, the mold including a void, forming a self-assembled layer from a self-assembled layer precursor in the void of the mold, removing the mold, and forming an organic semiconductor on the gate insulating layer.

### CROSS REFERENCE TO RELATED APPLICATIONS

This application claims priority to and the benefit of Korean Patent Application No. 10-2016-0141282 filed in the Korean Intellectual Property Office on Oct. 27, 2016, the entire contents of which are incorporated herein by reference.

### BACKGROUND

### 1. Field

Example embodiments relate to a method of manufacturing a thin film transistor, a thin film transistor, and an electronic device including the same.

### 2. Description of the Related Art

A flat panel display (e.g., a liquid crystal display (LCD), an organic light emitting diode (OLED) display and/or an electrophoretic display) includes multiple pairs of field generating electrodes and an electro-optical active layer disposed therebetween. The liquid crystal display (LCD) includes an electro-optical active layer of a liquid crystal layer, and the organic light emitting diode (OLED) display includes an electro-optical active layer of an organic emission layer.

One of paired field generating electrodes are generally connected to a switch and applied with an electrical signal, and the electro-optical active layer transforms the electrical signal to an optical signal to display an image.

The flat panel display includes a three-terminal element of a thin film transistor (TFT) as a switch.

Among the thin film transistors, an organic thin film transistor (OTFT) including an organic semiconductor (e.g., a relatively low molecular compound or a polymer) instead of the inorganic semiconductor (e.g., silicon (Si)) has been actively researched.

The organic thin film transistor may be made into a fiber or a film due to characteristics of an organic material and thus draws attention as an essential device based on flexibility such as a flexible display device, a wearable display device, etc. other than a flat panel display and may also be applied to various electronic devices based on a thin film transistor, (e.g., RFID (radio frequency identification) tag, various sensors, etc.) other than the display devices.

One example of patterning the organic semiconductor may include selective deposition of an organic semiconductor material using a shadow mask, but the organic semiconductor is difficult to precisely deposit.

Another example of patterning the organic semiconductor may include forming a photoresist on the organic semiconductor, but a given or predetermined fluorine-based photoresist not reacting with the organic semiconductor should be used in order to reduce or prevent damage to the organic semiconductor and thus may increase a manufacturing cost.

### SUMMARY

Example embodiments provide a method of manufacturing a thin film transistor capable of reducing damage to an organic semiconductor and securing precision of a pattern.

Example embodiments also provide a thin film transistor manufactured using the manufacturing method.

Example embodiments also provide an electronic device including the thin film transistor.

According to example embodiments, a method of manufacturing an organic thin film transistor includes forming a gate electrode, forming a gate insulating layer on the gate electrode, forming a mold on the gate insulating layer, forming a self-assembled layer from a self-assembled layer precursor in a void of the mold, removing the mold, and forming an organic semiconductor on the gate insulating layer.

An area occupied with the self-assembled layer may be defined by the void of the mold.

The void of the mold may be formed to partially expose the upper surface of the gate insulating layer.

The forming of the mold on the gate insulating layer may include forming a material layer on the gate insulating layer, forming a photoresist on the material layer, selectively removing the photoresist and the material layer to expose the gate insulating layer, and removing a remaining photoresist on the material layer to form a void of the mold.

The forming of the material layer may include applying a metal, a semi-metal, a polymer, or a combination thereof on the gate insulating layer.

The applying of the metal, the semi-metal, the polymer, or the combination thereof may be performed depending on their deposition manners.

The metal may include a transition metal, a post-transition metal, an alkali metal, an alkaline-earth metal, or a combination thereof.

The exposure of the upper surface of the gate insulating layer may include exposing the photoresist with a mask, developing the exposed photoresist, and etching the material layer exposed by developing the photoresist.

The etching of the material layer may be dry etching.

The forming of the organic semiconductor may be performed in a solution coating or deposition method.

The self-assembled layer may be directly on the gate insulating layer.

The self-assembled layer precursor may include a compound represented by Chemical Formula 1.

X—Y—Z [Chemical Formula 1]

In Chemical Formula 1,

X is —SiX₁X₂X₃, —COOH, —SOOH, —PO₃H, —SO₃H₂, —COCl, —PO₃H, —SO₂Cl, —OPOCl₂, —POCl₂, or a combination thereof, wherein X₁, X₂, and X₃ are independently hydrogen, a substituted or unsubstituted C₁ to C₂₀ alkoxy group, a hydroxy group, or a halogen,

Y is —(CH₂)n- (wherein n is an integer of 0 to 30) or —(CF₂)m- (wherein m is an integer of 0 to 30), or a combination thereof, and

Z is hydrogen, a hydroxy group, a substituted or unsubstituted C₁ to C₂₀ alkyl group, a substituted or unsubstituted C₆ to C₂₀ aryl group, a substituted or unsubstituted C₁ to C₂₀ haloalkyl group, a halogen, a thiol group, amine group, a nitro group or a combination thereof.

Before forming the self-assembled layer, the surface of the gate insulating layer may be treated with oxygen plasma or UV.

According to example embodiments, a thin film transistor manufactured by the manufacturing method.

According to example embodiments, an electronic device includes the thin film transistor.

The electronic device may include one of a liquid crystal display (LCD), an organic light emitting diode (OLED) display, an electrophoretic display, and an organic sensor.

The method may reduce or minimize damage to an organic semiconductor and secure a precise pattern during the process. In addition, because the organic semiconductor needs no separate patterning process using an expensive fluorine-based photoresist not reacting with the organic semiconductor, a manufacturing cost may be reduced.

### BRIEF DESCRIPTION OF THE DRAWINGS

FIG. 1 is a cross-sectional view showing a thin film transistor manufactured according to a method of manufacturing a thin film transistor according to example embodiments,

FIG. 2 is a cross-sectional view showing a thin film transistor manufactured according to a method of manufacturing a thin film transistor according to example embodiments,

FIG. 3 is a flowchart showing a method of manufacturing a thin film transistor according to example embodiments,

FIGS. 4 to 13 are views sequentially showing a process of manufacturing the thin film transistor according to example embodiments,

FIG. 14 is a view showing the device of FIG. 13 from a top view,

FIG. 15 is a graph showing charge mobility of an organic thin film transistor according to Example 1,

FIG. 16 is a graph showing charge mobility of an organic thin film transistor according to Comparative Example 1,

FIG. 17 is an atomic force microscope (AFM) image showing an organic semiconductor formed on the surface of a self-assembled layer in an organic semiconductor of the organic thin film transistor according to Example 1, and

FIG. 18 is an atomic force microscope (AFM) image showing an organic semiconductor formed on the surface of a gate insulating layer in the organic semiconductor of the organic thin film transistor according to Example 1.

### DETAILED DESCRIPTION

Hereinafter, example embodiments will hereinafter be described in detail with reference to the accompanying drawings. However, this disclosure is not to be construed as limited to the example embodiments set forth herein and may be embodied in many different forms.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

It should be understood that, although the terms first, second, third, etc. may be used herein to describe various elements, components, regions, layers and/or sections, these elements, components, regions, layers, and/or sections should not be limited by these terms. These terms are only used to distinguish one element, component, region, layer, or section from another region, layer, or section. Thus, a first element, component, region, layer, or section discussed below could be termed a second element, component, region, layer, or section without departing from the teachings of example embodiments.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

The terminology used herein is for the purpose of describing various embodiments only and is not intended to be limiting of example embodiments. As used herein, the singular forms “a,” “an,” and “the” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

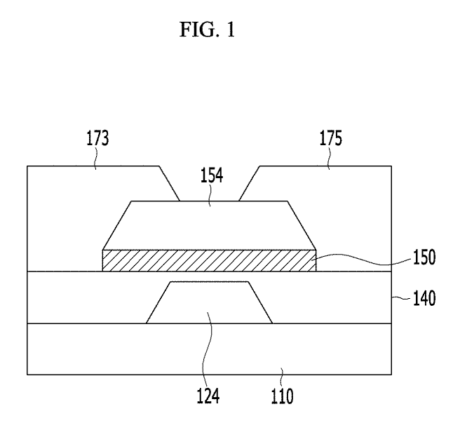

First, the schematic structure of a thin film transistor according to example embodiments is illustrated referring to FIG. 1.

FIG. 1 is a cross-sectional view showing an organic thin film transistor according to example embodiments.

Referring to FIG. 1, a gate electrode 124 is formed on a substrate 110.

The substrate 110 may at least partially comprise, for example, transparent glass, silicon, or a polymer. The gate electrode 124 is connected to a gate line (not shown) transmitting a data signal, and may at least partially comprise, for example, gold (Au), copper (Cu), nickel (Ni), aluminum (Al), molybdenum (Mo), chromium (Cr), tantalum (Ta), titanium (Ti), tungsten (W), indium tin oxide (ITO), indium zinc oxide (IZO), or an alloy thereof, or polythiophene, polyaniline, polyacetylene, polypyrrole, polyphenylenevinylene, PEDOT (polyethylene dioxythiophene), PSS (polystyrenesulfonate), and a combination thereof, but is not limited thereto.

A gate insulating layer 130 is formed on the gate electrode 124.

The gate insulating layer 130 may at least partially comprise an organic material or an inorganic material, examples of the organic material may include a soluble polymer compound such as a polyvinyl alcohol-based compound, a polyimide-based compound, a polyacryl-based compound, a polystyrene-based compound, and benzocyclobutane (BCB), and examples of the inorganic material may include a silicon nitride (SiNₓ) and a silicon oxide (SiO₂).

Via holes are formed in the gate insulating layer 130 so that the gate insulating layer 130 and the gate electrode 124 formed in subsequent processes are electrically connected to each other.

A self-assembled layer 150 is formed on the gate insulating layer 140.

The self-assembled layer 150 may at least partially comprise, for example, a self-assembled monolayer precursor having one terminal end or both terminal ends having affinity for an insulator.

The precursor of the self-assembled layer 150 may include, for example, a compound represented by Chemical Formula 1.

X—Y—Z [Chemical Formula 1]

In Chemical Formula 1,

X is —SiX₁X₂X₃, —COOH, —SOOH, —PO₃H, —SO₃H₂, —COCl, —PO₃H, —SO₂Cl, —OPOCl₂, —POCl₂, or a combination thereof, wherein each of X₁, X₂, and X₃ are independently hydrogen, a substituted or unsubstituted C₁ to C₂₀ alkoxy group, a hydroxy group, or a halogen,

Y is —(CH₂)n- (wherein n is an integer of 0 to 30) or —(CF₂)m- (wherein m is an integer of 0 to 30), or a combination thereof, and

Z is hydrogen, a hydroxy group, a substituted or unsubstituted C₁ to C₂₀ alkyl group, a substituted or unsubstituted C₆ to C₂₀ aryl group, a substituted or unsubstituted C₁ to C₂₀ haloalkyl group, a halogen, a thiol group, amine group, a nitro group or a combination thereof.

For example, the precursor of the self-assembled layer 150 may be compounds of Group 1, but is not limited thereto.

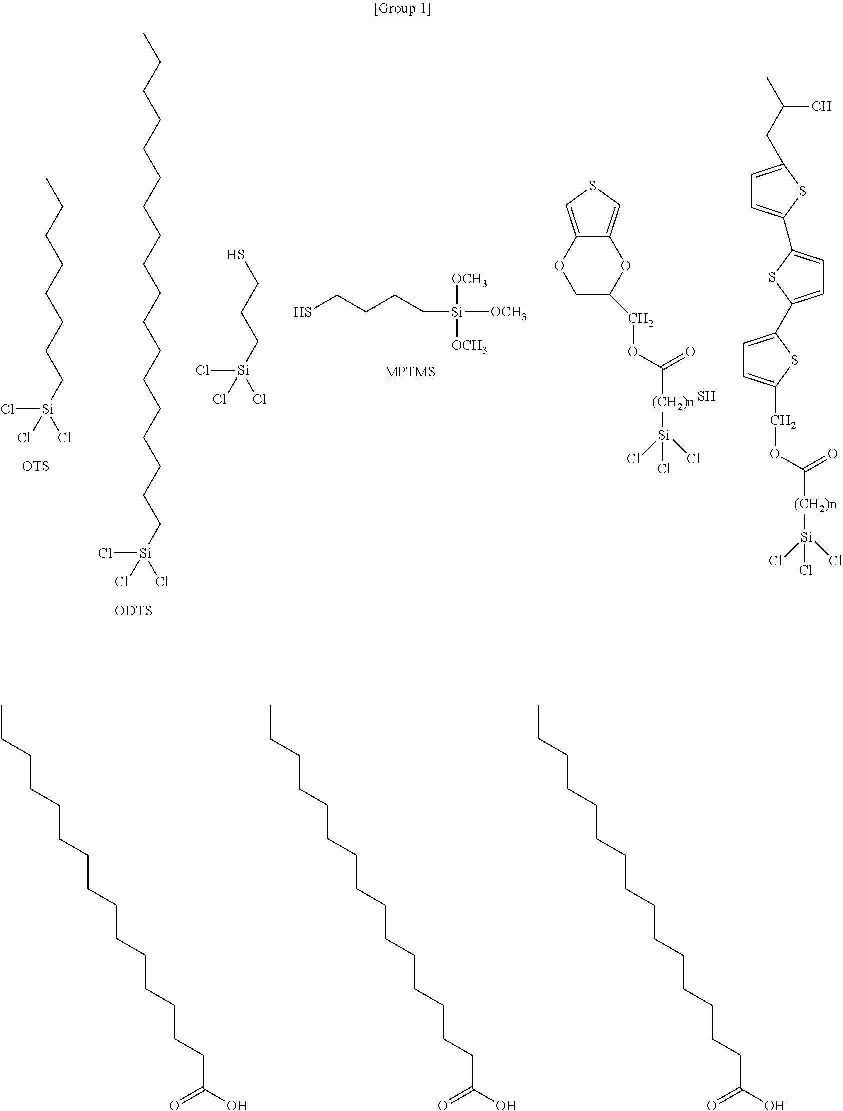

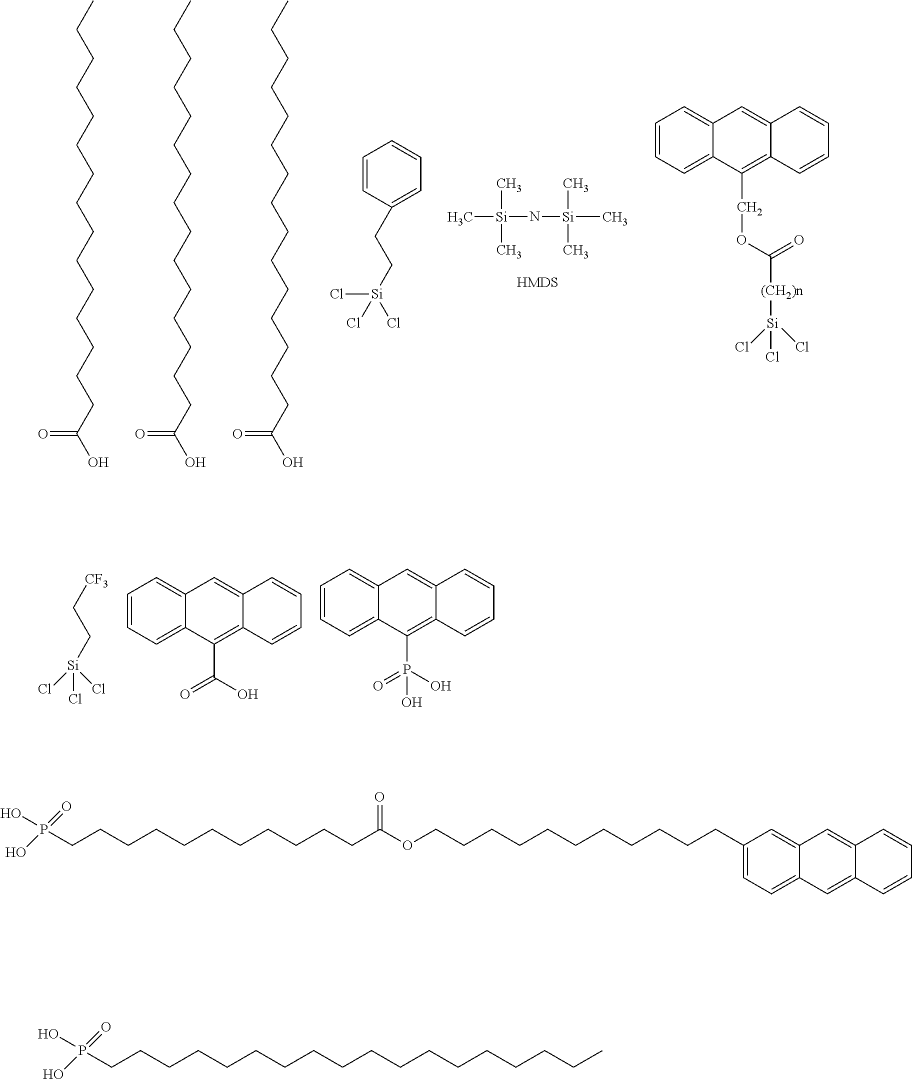

On the other hand, an organic semiconductor 154 is formed on the gate insulating layer 140 and the self-assembled layer 150.

The organic semiconductor 154 may at least partially comprise one selected from pentacene and a precursor thereof, tetrabenzoporphyrin and a precursor thereof, polyphenylenevinylene and a precursor thereof, polyfluorene and a precursor thereof, polythienylenevinylene and a precursor thereof, polythiophene and a precursor thereof, polythienothiophene and a precursor thereof, polyarylamine and a precursor thereof, phthalocyanine and a precursor thereof, metallized phthalocyanine or a halogenated derivative thereof, perylenetetracarboxylic dianhydride (PTCDA), naphthalene tetracarboxylic dianhydride (NTCDA) or an imide derivative thereof, perylene or coronene, and a substituent-containing derivatives thereof.

The self-assembled layer 150 is formed between the organic semiconductor 154 and the gate insulating layer 140 and may improve molecular array of an organic semiconductor material and thus reduce defects in a region where a channel of a thin film transistor is formed and improve charge mobility of the thin film transistor.

A source electrode 173 and a drain electrode 175 are formed on the self-assembled layer 150.

The source electrode 173 and the drain electrode 175 face each other in a center of the gate electrode 124. The source electrode 173 is electrically connected with a data line (not shown) for transferring a data signal.

The source electrode 173 and the drain electrode 175 may include at least one metal selected from gold (Au), copper (Cu), nickel (Ni), silver (Ag), aluminum (Al), molybdenum (Mo), chromium (Cr), tantalum (Ta), and titanium (Ti), or an alloy thereof.

FIG. 1 shows a thin film transistor having an upper contact (a top contact) structure as one example of a thin film transistor, but the present disclosure is not limited thereto and may be applied to a thin film transistor having all the structures including a bottom contact structure.

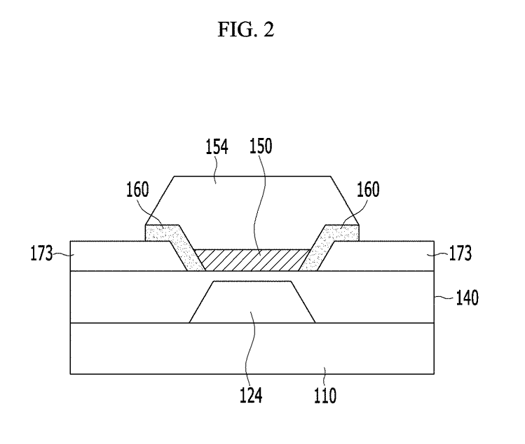

FIG. 2 is a cross-sectional view showing an organic thin film transistor according to example embodiments. The organic thin film transistor shown in FIG. 2 has a bottom contact structure.

For example, as shown in FIG. 1, the self-assembled layer 150 may be formed directly on the gate insulating layer 140, but according to example embodiments, as shown in FIG. 2, the self-assembled layers 150 and 160 may be formed directly on the gate insulating layer 140 and/or directly on the source electrode 173 and the drain electrode 175. Referring to FIG. 2, the self-assembled layer 150 formed between the organic semiconductor 154 and gate insulating layer 140 may improve molecular array of an organic semiconductor material and thus reduce defects in a region where a channel of a thin film transistor is formed and improve charge mobility, and the self-assembled layer 160 between the organic semiconductor 154 and the source electrode 173 and between the organic semiconductor 154 and the drain electrode 175 plays a role of a charge injection layer and decreases contact resistance therebetween and increases charge mobility.

The precursor of the self-assembled layer 160 may include, for example a thiol-based compound, a thioacetyl-based compound, a disulfide-based compound, or a combination thereof.

For example, the precursor of the self-assembled layer 160 may be compounds of Group 2, but is not limited thereto.

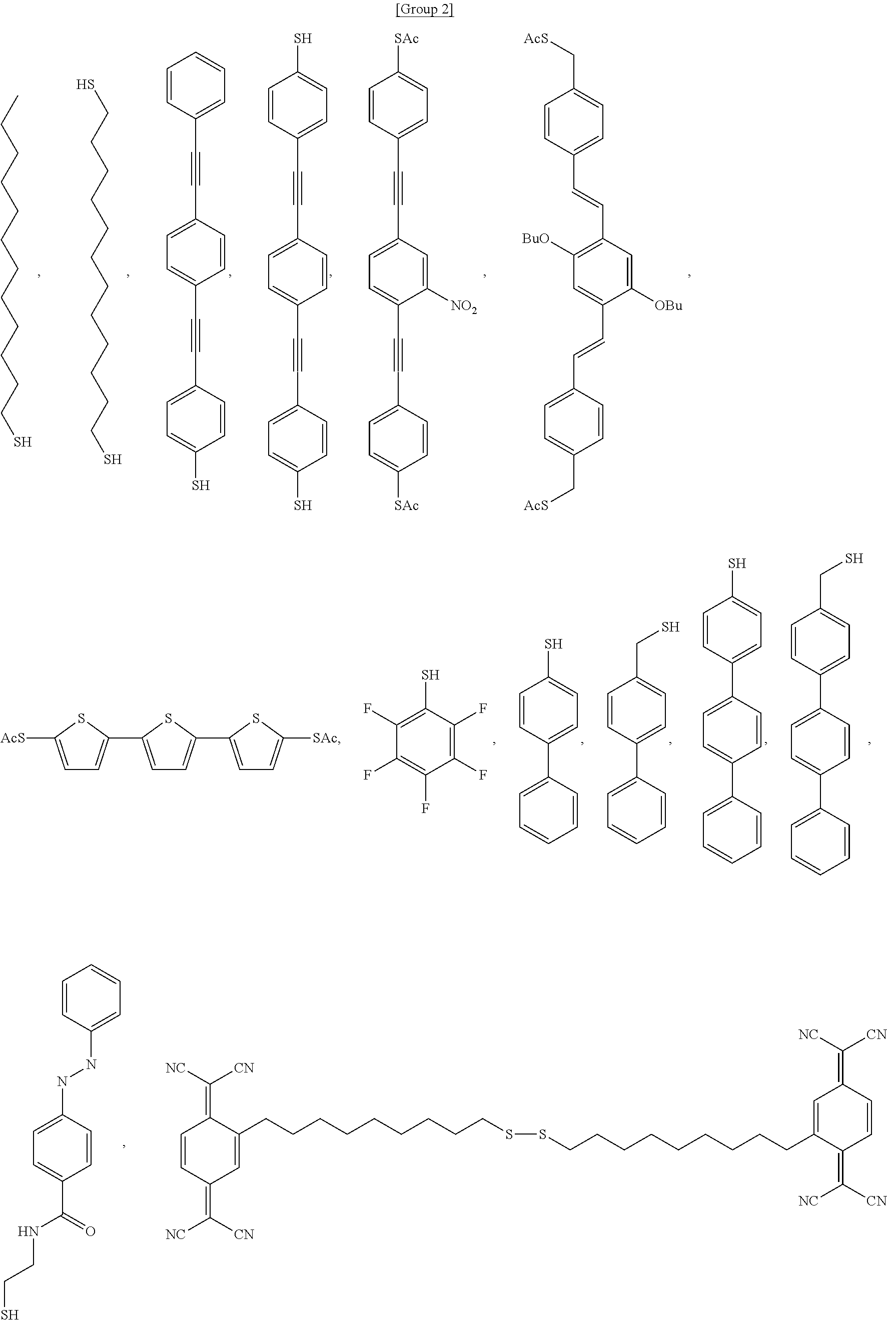

The precursor of the self-assembled layer 160 may include, for example a fluorine-containing thiol-based compound such as pentafluorobenzene thiol of Group 2.

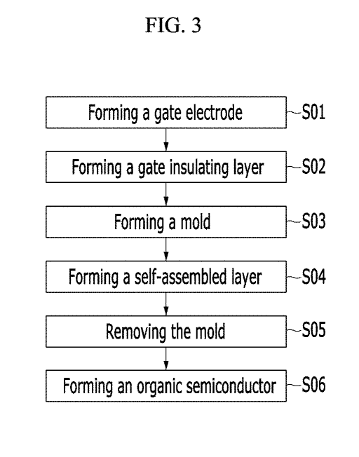

Hereinafter, a method of manufacturing the organic thin film transistor is illustrated referring to FIGS. 3 to 12 along with FIG. 1.

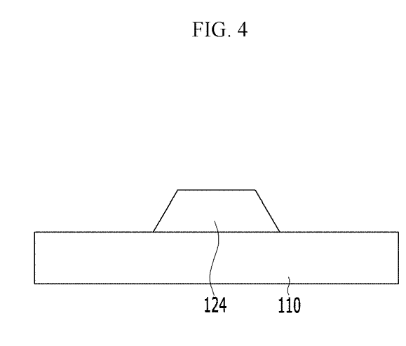

FIG. 3 is a flowchart showing a method of manufacturing a thin film transistor according to example embodiments, and FIGS. 4 to 13 are views sequentially showing a process of manufacturing the thin film transistor according to example embodiments.

Referring to FIG. 3, the method of manufacturing the thin film transistor according to example embodiments includes forming a gate electrode (S01), forming a gate insulating layer (S02), forming a mold (S03), forming a self-assembled layer (S04), removing the mold (S05), and forming an organic semiconductor (S06).

Referring to FIG. 4, the gate electrode 124 is formed by sputtering a conductive layer on the substrate 110 in the formation of the gate electrode (S01) and then, treating the gate electrode through photolithography.

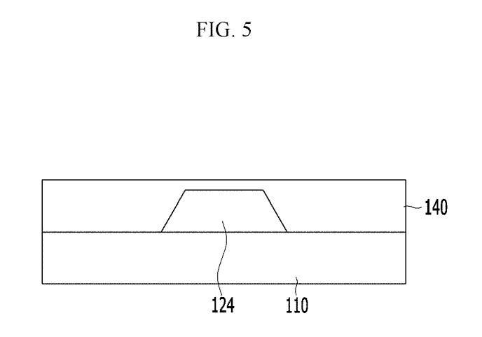

Then, referring to FIG. 5, the gate insulating layer 140 is formed on the gate electrode 124 in the formation of the gate insulating layer (S02). The gate insulating layer 140 may be formed by using a dry process such as a chemical vapor deposition (CVD) or a solution process such as spin coating and Inkjet printing.

The gate insulating layer 140 has a via hole through which the gate insulating layer 140 is electrically connected with the gate electrode 124 in the subsequent process.

After forming the gate insulating layer 140, the mold is formed (S03).

Herein, the mold is a frame for forming the self-assembled layer 150. The mold includes a void, and this void defines an area occupied with the self-assembled layer 150. This will be described later in detail.

A material for the mold may be a metal such as a transition metal, a post-transition metal, an alkali metal, an alkaline-earth metal, or a combination thereof or a polymer but is not limited thereto.

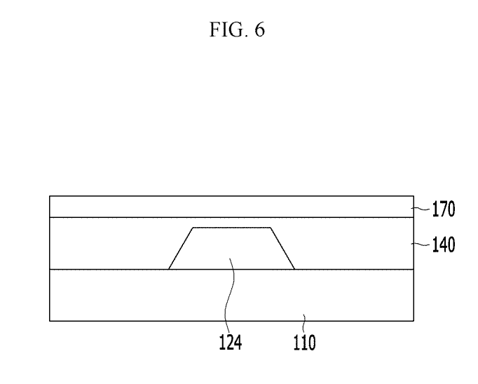

The formation of the mold (S03) is illustrated referring to FIGS. 6 to 10.

The formation of the mold (S03) on the gate insulating layer 140 according to example embodiments includes forming the material layer 170 on the gate insulating layer 140, forming the photoresist 180 on the material layer 170, exposing the upper surface of the gate insulating layer 140 by selectively removing the photoresist 180 and the material layer 170, and forming the void (V) by removing the photoresist 180 remaining on the material layer 170.

Referring to FIG. 6, the material layer 170 is formed on the gate insulating layer 140.

The material layer 170 is formed by applying a material (e.g., a metal, a semi-metal, or a polymer) on the gate insulating layer 140.

The material may be a metal, for example, a transition metal, a post-transition metal, an alkali metal, an alkaline-earth metal, or a combination thereof, or may be a polymer. For example, the material may include at least one metal selected from gold (Au), copper (Cu), nickel (Ni), silver (Ag), aluminum (Al), molybdenum (Mo), chromium (Cr), tantalum (Ta) and titanium (Ti), or an alloy thereof.

The material layer 170 is, for example, formed using a dry process such as chemical vapor deposition (CVD) or a solution process such as spin coating and inkjet printing.

The material layer 170 may have various thicknesses corresponding to a condition of the subsequent process of forming the self-assembled layer (S04), for example, a substantially equivalent thickness to that of the self-assembled layer.

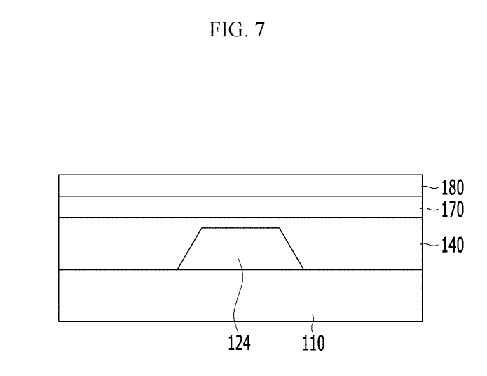

Then, referring to FIG. 7, the photoresist 180 is formed on the material layer 170.

The photoresist 180 may be, for example, formed in a dry process (e.g., a chemical vapor deposition (CVD)) or a solution process (e.g., spin coating and Inkjet printing) and formed of various materials without a particular limit.

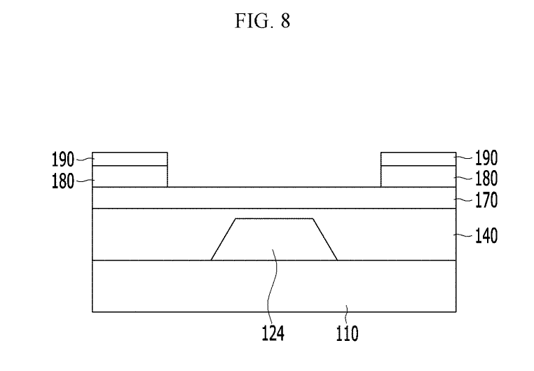

Subsequently, referring to FIG. 8, the upper surface of the gate insulating layer 140 may be exposed by selectively removing the photoresist 180 and the material layer 170.

First, the photoresist 180 is, for example, exposed to UV light using the mask 190 and then, developed. Accordingly, a part of the upper surface of the material layer 170 is exposed.

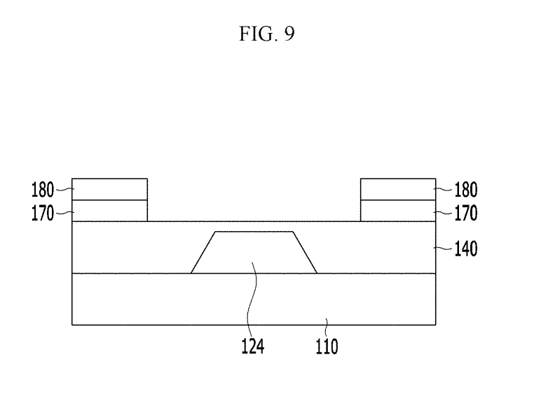

Then, referring to FIG. 9, the material layer 170 exposed through the development of the photoresist 180 is etched.

The etching of the material layer 170 may be, for example, wet etching using an etchant or dry etching (e.g., reactive ion etching (RIE)) using oxygen plasma.

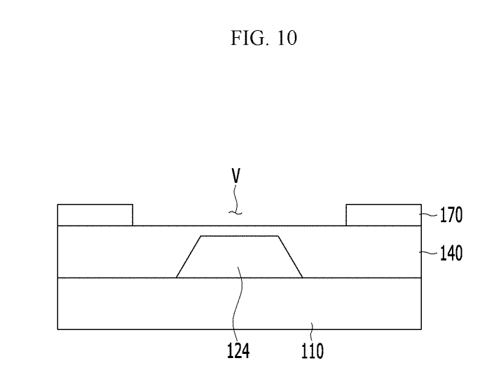

Then, referring to FIG. 10, the photoresist 180 remaining on the material layer 170 may be removed to form the void (V) of the mold. In FIG. 10, the mold is the material layer 170 remaining after the etching. However, the mold may be formed in various methods without a particular limit as long as it is any frame for forming the self-assembled layer 150. For example, when a mold is formed of a metal thin film, a photoresist is relatively more easily removed in a subsequent process than when a photoresist is directly formed as a mold on a gate insulating layer.

The void (V) of the mold is formed to expose a part of the upper surface of the gate insulating layer.

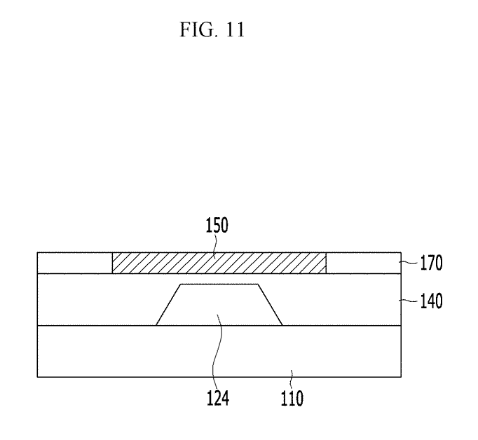

Then, referring to FIG. 11, the self-assembled layer 150 is formed in the void of the mold 170 (S04).

When self-assembled layer precursors are supplied on the gate insulator 140, the self-assembled layer precursors 151 are self-arranged on the gate insulator 140 to form the self-assembled layer 150. The self-assembled layer precursor and the self-assembled layer are the same as described above.

Before forming the self-assembled layer 150, the surface of the gate insulating layer 140 may be pre-treated. The pre-treatment is performed to activate the surface of the gate insulator 140 and thus easily react it with the precursors of the self-assembled layer 150 that will be described later. The pretreatment may be omitted. The pretreatment may be performed by treating the gate insulating layer 140 with oxygen plasma or UV-ozone.

The self-assembled layer 150 may be, for example, formed by dipping, depositing, or spin coating. The self-assembled layer 150 may be, for example formed by a solution process. A solvent for the solution process may be, for example an aliphatic hydrocarbon solvent such as hexane; an aromatic hydrocarbon solvent such as anisole, mesitylene, and xylene; a ketone based solvent such as methylisobutylketone, 1-methyl-2-pyrrolidinone, and acetone; an ether based solvent such as cyclohexanone, tetrahydrofuran, and isopropylether; an acetate based solvent such as ethylacetate, butylacetate, and propylene glycolmethyletheracetate; an alcohol based solvent such as isopropyl alcohol, and butanol; an amide based solvent such as dimethyl acetamide, and dimethyl formamide; a silicon-based solvent; or a combination thereof, but is not limited thereto.

The self-assembled layer 150 according to example embodiments is locally formed on the gate insulating layer 140 using the mold.

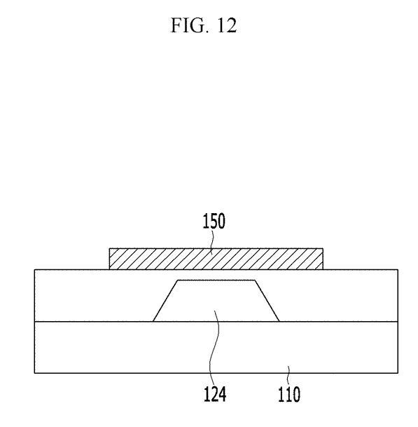

Subsequently, referring to FIG. 12, the mold formed on the gate insulating layer 140 is removed.

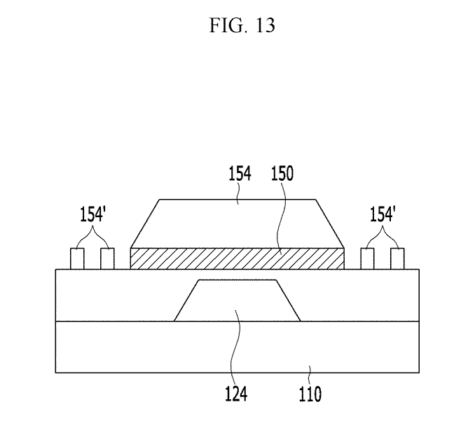

Then, referring to FIG. 13, the organic semiconductor 154 is formed on the gate insulating layer 140. The organic semiconductor 154 may be formed in a dry process such as a chemical vapor deposition (CVD) or a solution process such as spin coating and Inkjet printing.

The organic semiconductor 154 may have for example different growth morphology depending on surface energy despite deposition of the same material. The gate insulating layer 140 and the self-assembled layer 150 have different surface energy, and accordingly, an organic semiconductor 154′ on the surface of the gate insulating layer 140 has different growth morphology from the organic semiconductor 154 on the surface of the self-assembled layer 150. Because of this morphology difference, the organic semiconductor 154 on the surface of the self-assembled layer 150 has high linking among domains and show relatively high charge mobility and thus a sufficient current flow compared with the organic semiconductor 154′ on the surface of the gate insulating layer 140. On the other hand, the organic semiconductor 154′ on the surface of the gate insulating layer 140 has almost no linking among domains and shows relatively low charge mobility and thus almost no current flow compared with the organic semiconductor 154 on the surface of the self-assembled layer 150.

According to example embodiments, the organic semiconductor 154 may be patterned only through deposition without a separate patterning process using the growth morphology difference of the organic semiconductor 154. Accordingly, a manufacturing process may be simplified, and a manufacturing cost may be reduced due to the lack of an expensive mask for the organic semiconductor patterning.

In FIG. 13, the organic semiconductor 154 on the surface of the gate insulating layer 140 has almost no linking among domains and thus shows no current flow and resultantly, has no substantial influence on characteristics of a final product. Therefore, the organic semiconductor 154 on the surface of the gate insulating layer 140 may not be separately removed.

The organic semiconductor 154 may be, for example, formed in a deposition method, and the deposition may be under an appropriate condition for forming the organic semiconductor 154 more on the self-assembled layer 150 than the gate insulating layer 140. For example, a temperature, a speed, etc. for the deposition may be determined considering a type of material for the organic semiconductor 154. Non-limiting examples of the deposition may be for example performed at a substrate temperature ranging from about 100° C. to about 150° C., for example, at a speed of about 0.01 Å/s to about 0.1 Å/s but are not limited thereto.

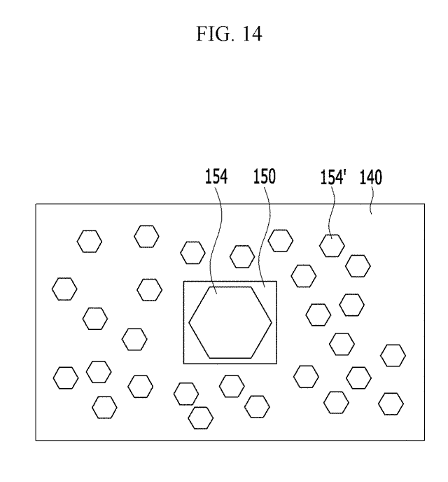

FIG. 14 is a view showing the device of FIG. 13 when viewed from the top view.

Referring to FIG. 14, the organic semiconductor 154 on the surface of the self-assembled layer 150 shows a higher linking degree among domains than the organic semiconductor 154′ on the surface of the gate insulating layer 140.

A method of manufacturing an organic thin film transistor according to example embodiments includes locally forming the self-assembled layer 150 on the gate insulating layer 140, forming the organic semiconductor 154 on the gate insulating layer 140, and resultantly, forming the organic semiconductor 154 on surface of the gate insulating layer 140 and particularly, on the surface of the self-assembled layer 150. In addition, the self-assembled layer 150 formed on the gate insulating layer 140 by using a given or predetermined mold may for example repetitively realize a precise pattern compared with a self-assembled layer formed in a stamping method and thus increase reliability of a device.

The organic thin film transistor manufactured according to the method may be applied to various display devices. The display device may be, for example a liquid crystal display (LCD), an organic light emitting diode (OLED) display, an electrophoretic display, etc., but is not limited thereto.

Hereinafter, the present disclosure is illustrated in more detail with reference to examples. However, these are examples, and the present disclosure is not limited thereto.

### Manufacture of Thin Film Transistor

### EXAMPLE 1

A gate electrode is formed by sputtering molybdenum on an Si substrate and treating it through photolithography. Subsequently, a gate insulating layer is formed thereon by depositing silicon oxide in a chemical vapor deposition (PECVD) method. Then, a 1000 Å-thick metal thin film is formed by depositing molybdenum on the gate insulating layer in the chemical vapor deposition (CVD) method. On the metal thin film, a photoresist is coated and cured. Subsequently, a resulting product therefrom is ultraviolet (UV)-treated by using a photomask capable of defining an area of a self-assembled layer and cured. After dissolving the metal thin film with an etchant, the photoresist is removed. Subsequently, the surface of the gate insulating layer is activated through an oxygen plasma process (100 W, 30 seconds).

Then, the self assembled layer is formed by using octadecyltrichlorosilane (ODTS) on the surface of the gate insulating layer. Specifically, the Si substrate is dipped in a solution obtained by diluting the octadecyltrichlorosilane (ODTS) into a concentration of 5 mMol in hexane and allowing it to stand for one hour. Subsequently, the substrate is taken therefrom to remove a nonreacted material on the substrate with hexane and ethanol and then, heat-treated to react the nonreacted material. Subsequently, the metal thin film is dissolved with an etchant. Then, a heteroacene-based organic semiconductor represented by Chemical Formula a is deposited to form a 500 Å-thick organic semiconductor thin film. Subsequently, a source electrode and a drain electrode are formed by thermally depositing gold (Au) and treating it through photolithography to manufacture a thin film transistor.

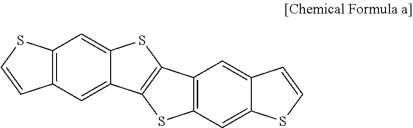 [SMILES: c1cc2cc3c(cc2s1)sc1c2cc4ccsc4cc2sc31]

### COMPARATIVE EXAMPLE 1

A gate electrode is formed by sputtering molybdenum on an Si substrate and treating it through photolithography. Subsequently, a gate insulating layer is formed by depositing silicon oxide in a chemical vapor deposition (PECVD) method. The surface of the gate insulating layer is activated through an oxygen plasma process (100 W, 30 seconds). On the surface of the gate insulating layer, a self assembled layer is formed by using octadecyltrichlorosilane (ODTS). The self assembled layer is formed under the same condition of Example 1. Subsequently, a heteroacene-based organic semiconductor represented by Chemical Formula a is deposited to form a 500 Å-thick organic semiconductor thin film. On the organic semiconductor thin film, a fluorine-based photoresist (Orthogonal Inc.) is coated and cured. Subsequently, the organic semiconductor thin film is UV treated by using the photomask and then developed to form a pattern. The rest part of the organic semiconductor except for the pattern is removed through dry etching. Subsequently, the remaining photoresist is removed. Then, a source electrode and a drain electrode are formed by sputtering gold (Au) and treating it through photolithography to manufacture a thin film transistor.

### Evaluation 1

Charge mobility of the organic thin film transistors according to Example 1 and Comparative Example 1 is evaluated. The charge mobility is evaluated by using a semiconductor analyzer (4200-SCS, Keithley Instruments Inc.).

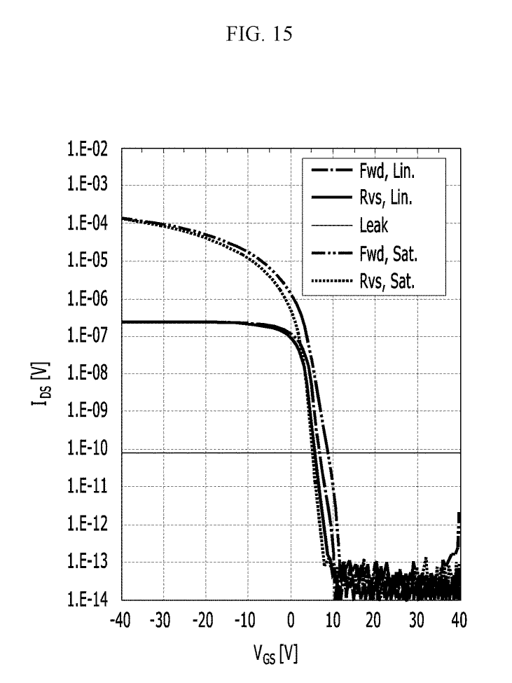

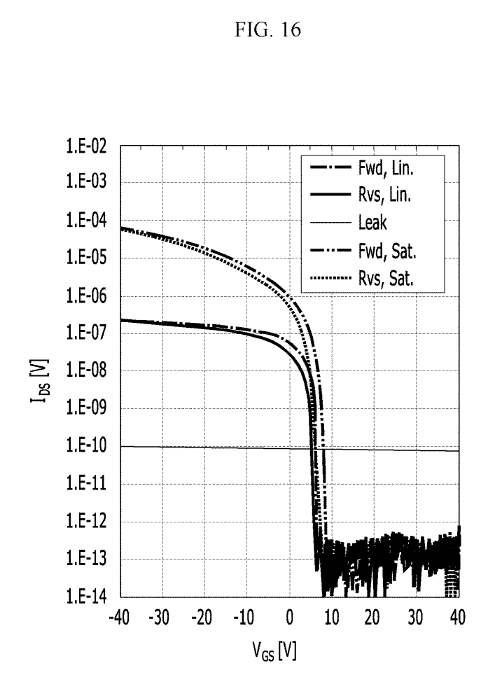

The results are shown in Table 1 and FIGS. 15 and 16.

FIG. 15 is a graph showing the charge mobility of the organic thin film transistor according to Example 1, and FIG. 16 is a graph showing charge mobility of the organic thin film transistor according to Comparative Example 1.

TABLE 1

| | Charge mobility (cm²/Vs) |
|---|---|
| Example 1 | 8.8 |
| Comparative Example 1 | 5.8 |

Referring to Table 1 and FIGS. 15 and 16, the organic thin film transistor manufactured by patterning a self-assembled layer on a gate insulating layer and forming the organic semiconductor 154 thereon according to Example 1 shows excellent charge mobility compared with the organic thin film transistor manufactured by patterning an organic semiconductor with a fluorine-based photoresist according to Comparative Example 1.

### Evaluation 2

A linking degree of organic semiconductor domains of the organic thin film transistor of Example 1 is examined through an atomic force microscope (AFM) image.

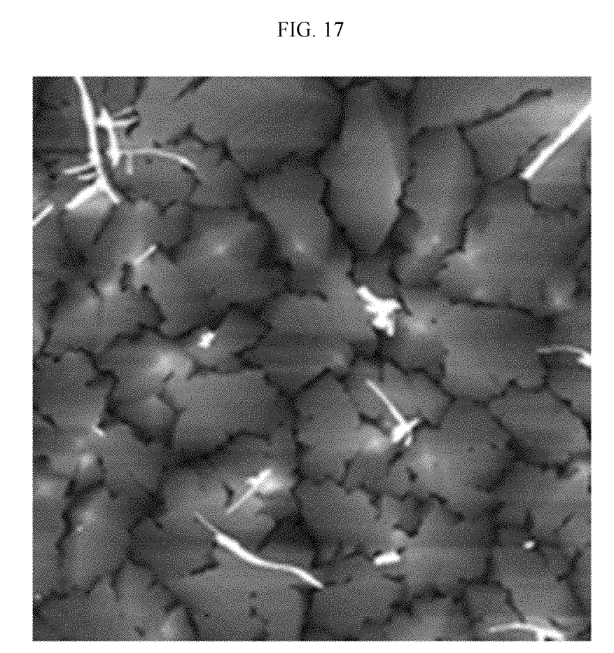

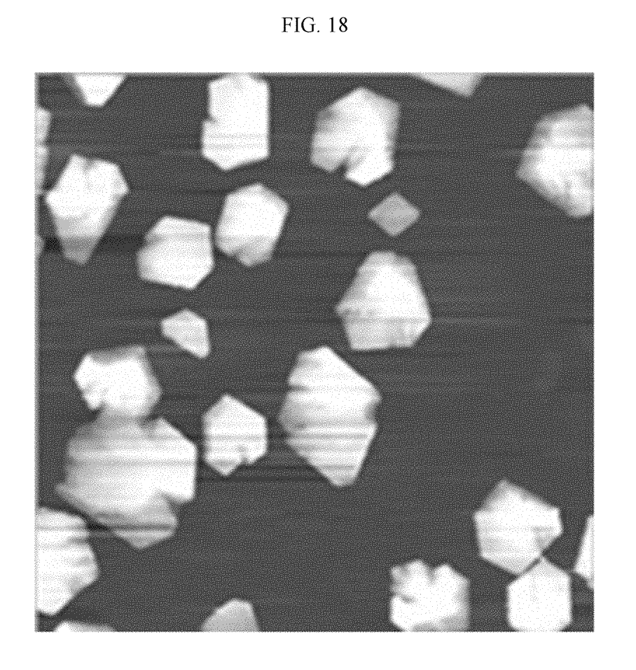

FIG. 17 is an atomic force microscope (AFM) image showing the organic semiconductor on the surface of the self-assembled layer in the organic semiconductor of the organic thin film transistor according to Example 1, and FIG. 18 is an atomic force microscope (AFM) image showing the organic semiconductor on the surface of the gate insulating layer in the organic semiconductor of the organic thin film transistor according to Example 1.

Referring to FIGS. 17 and 18, in the organic semiconductor of the organic thin film transistor according to Example 1, the organic semiconductor formed on the surface of the self-assembled layer shows sufficient inking among the domains compared with the organic semiconductor formed on the surface of the gate insulating layer.

While this disclosure has been described in connection with what is presently considered to be practical example embodiments, it is to be understood that the inventive concepts are not limited to the disclosed embodiments, but, on the contrary, is intended to cover various modifications and equivalent arrangements included within the spirit and scope of the appended claims.

What is claimed is:

1. A method of manufacturing an organic thin film transistor, comprising:
forming a gate electrode;
forming a gate insulating layer on the gate electrode;
forming a mold on the gate insulating layer, the mold including a void;
forming a self-assembled layer from a self-assembled layer precursor in the void of the mold;
removing the mold; and
forming an organic semiconductor on the gate insulating layer.

2. The method of claim 1, wherein an area occupied by the self-assembled layer is defined by the void of the mold.

3. The method of claim 1, wherein the forming a mold including the void exposes a portion of an upper surface of the gate insulating layer.

4. The method of claim 1, wherein the forming a mold includes:
forming a material layer on the gate insulating layer;
forming a photoresist on the material layer;
selectively removing the photoresist and the material layer to expose the gate insulating layer; and
removing a remaining photoresist on the material layer.

5. The method of claim 4, wherein the forming a material layer includes applying a metal, a semi-metal, a polymer, or a combination thereof.

6. The method of claim 5, wherein the metal, the semi-metal, the polymer, or the combination thereof are applied depending on a deposition method.

7. The method of claim 5, wherein the metal includes a transition metal, a post-transition metal, an alkali metal, an alkaline-earth metal, or a combination thereof.

8. The method of claim 4, wherein the exposing an upper surface of the gate insulating layer comprises:
exposing the photoresist by a mask;
developing the exposed photoresist; and
etching the material layer exposed by developing the photoresist.

9. The method of claim 8, wherein the etching the material layer dry etches the material layer.

10. The method of claim 1, wherein the forming an organic semiconductor includes a solution coating or deposition method.

11. The method of claim 1, wherein the forming a self-assembled layer directly forms the self-assembled layer on the gate insulating layer.

12. The method of claim 1, wherein the self-assembled layer precursor includes a compound represented by Chemical Formula 1:
X—Y—Z [Chemical Formula 1]
wherein, in Chemical Formula 1,
X is —SiX₁X₂X₃, —COOH, —SOOH, —PO₃H, —SO₃H₂, —COCl, —PO₃H, —SO₂Cl, —OPOCl₂, —POCl₂, or a combination thereof, wherein each of X₁, X₂, and X₃ are independently hydrogen, a substituted or unsubstituted C₁ to C₂₀ alkoxy group, a hydroxy group, or a halogen,
Y is —(CH₂)n- (wherein n is an integer of 0 to 30) or —(CF₂)m- (wherein m is an integer of 0 to 30), or a combination thereof, and
Z is hydrogen, a hydroxy group, a substituted or unsubstituted C₁ to C₂₀ alkyl group, a substituted or unsubstituted C₆ to C₂₀ aryl group, a substituted or unsubstituted C₁ to C₂₀ haloalkyl group, a halogen, a thiol group, amine group, a nitro group or a combination thereof.

13. The method of claim 1, further comprising:
surface-treating the gate insulating layer with oxygen plasma or UV before the forming a self-assembled layer.

14. An organic thin film transistor manufactured according to the method of claim 1.

15. An electronic device comprising the organic thin film transistor of claim 14.

16. The electronic device of claim 15, wherein the electronic device includes one from a liquid crystal display (LCD), an organic light emitting diode (OLED) display, an electrophoretic display, and an organic sensor.
